(19) United States
(12) Patent Application Publication
(10) Pub. No.: US 2003/0042404 A1
(43) Pub. Date: Mar. 6, 2003

(54) III-Nitride laser activated semiconductor switch and associated methods of fabrication and operation

(75) Inventors: Robert R. Rice, Simi Valley, CA (US); Neil F. Ruggieri, St. Louis, MO (US); J. Stanley Whiteley, Maryland Heights, MO (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: The Boeing Company

(21) Appl. No.: 09/946,899

(22) Filed: Sep. 5, 2001

(51) Int. Cl. H01L 31/00

(52) U.S. Cl. 250/214.1

(57) ABSTRACT

A laser activated switch includes a substrate, such as a sapphire or a silicon carbide substrate, with two opposed major surfaces including a ground layer on one surface. Extending laterally across the first surface of the substrate, the laser activated switch includes at least one pair of first and second electrically conductive electrodes. Each electrode of the pair of electrodes is spaced apart from one another to thereby define a gap. Additionally, the laser activated switch includes at least one III-nitride-based photoconductor extending laterally across at least part of the surface of the substrate opposite the ground layer, and extending across the gap defined between the pairs of electrodes. Upon being illuminated, the photoconductor becomes conductive and changes the switch from an “off” state to an “on” state. In one embodiment, the laser activated switch further includes first and second terminals electrically connected to the first and second electrodes, respectively.

### FIELD OF THE INVENTION

The present invention relates to switches and switching methods and, more particularly, to laser activated semiconductor switches and associated methods of fabrication and operation.

### BACKGROUND OF THE INVENTION

Many electrical systems today employ some type of switching procedure. As devices get more sophisticated, however, electronically performing switching functions becomes more difficult. Electrical switching often suffers from slow response times and electromagnetic interference, thus making it undesirable for many commercial, industrial and military applications. As a result of the deficiencies in conventional electrical switching, laser-activated semiconductor switching (LASS) switches have been developed. Among the many advantages of a LASS switch over an electrical switch, a conventional LASS switch generally has a switching speed at or above the rise time of the optical pulses triggering the switch.

LASS switches perform switching functions with photoconductive materials that have the ability to increase their electric conductivity, and thus reduce their resistance, with the introduction of light. Photoconductive materials will absorb the incident light having a frequency above a predetermined frequency established by the properties of the particular photoconductive material. When the light is absorbed by the photoconductive material, the photons of light cause electrons to move from the valence band to the conduction band. The resulting holes in the valence band permit electron flow and, hence, current flow through the photoconductive material. After a time period, called the carrier lifetime, the electrons return to the valence band, at which point the photoconductive material ceases to permit electron flow.

Conventional LASS switches are typically based on bulk silicon photoconductors that are driven into conduction by a laser, such as a pulsed Nd:YAG laser operating at 1064 nanometers. The single crystal photoconductors are fabricated from silicon boules by cutting, grinding and polishing to the final desired dimensions. The photoconductors are then metallized and soldered into a low impedance waveguide to thereafter generate of high power microwave pulses. Using different switch geometries and numbers of switches, such as in pulse generation with multiple switch, frozen-wave waveguide circuits, high frequency LASS microwave sources and/or photonically controlled power switches can be implemented using conventional silicon LASS switch technology.

Whereas these conventional LASS switches provide advantages over electrical switches, they suffer from several drawbacks. First, fabricating the silicon photoconductors and soldering them into the waveguide are costly and make up a major part of the cost of a LASS high power microwave source. Second, discontinuities in the waveguide caused by the silicon photoconductor, and the optical response time of the silicon LASS switch, limit implementation and operation above the x-band region of the radio frequency (RF) spectrum where smaller switch sizes and spacings, less than half the RF wavelength are required.

Third, the physical configuration of the silicon LASS switch results in inefficient use of laser light pumped into the photoconductor, and significant RF field penetration depth into the silicon with associated losses due to low carrier density and impedance changes in the waveguide. Fourth, because silicon is an indirect band-gap semiconductor with a long carrier life, silicon LASS switches do not quickly turn off. Additionally, the pulse repetition rate is limited because recharging the silicon LASS switch cannot commence until the silicon photoconductor has returned to a non-conductive state.

Fifth, silicon LASS switches suffer from drawbacks related to its temperature sensitivity. Because many applications require operation in high temperature environments, this is a substantial limitation of conventional silicon LASS switches. The narrow band gap of silicon, 1.11 electron volts (eV), leads to thermally generated carriers that contribute to current leakage and breakdown when high voltages are applied across the silicon LASS switch at high temperatures. In this regard, optical switching applications conducted at high temperatures are generally unable to adequately utilize silicon LASS switches due to the problems created by current leakage and breakdown and therefore degrade reliability.

### SUMMARY OF THE INVENTION

In light of the foregoing background, the present invention provides an improved laser activated semiconductor switching (LASS) switch and associated methods of fabrication and operation. The LASS of the present invention utilizes a photoconductor constructed from a wide band gap III-nitride (III-N) semiconductor film. The photoconducting properties of the III-N semiconductor film reduces the cost while improving the performance of the LASS switch of the present invention in relation to conventional silicon LASS switches. The photoconducting properties of III-N also allow the LASS switch of the present invention to operate as a monolithic, high frequency LASS microwave source and/or a photonically controlled power switch.

Advantageously, using a III-N based photoconductor makes the LASS of the present invention particularly suitable for high temperature applications. For example, depending upon the particular alloy composition, the band gap of the III-N semiconductor film can be quite large, such as 3 eV to 6 eV for an AlGaInN semiconductor film, thereby substantially reducing the thermally generated carriers that lead to current leakage and breakdown. The band gap is also direct over the entire range, so the optical absorption coefficient is very high and the carrier lifetime is short when compared with silicon semiconductors, with the predominant decay being radiative recombination. The direct band gap of these materials also enables the III-N LASS switch to be driven by a light source having lower power, such as an efficient light emitting diode (LED) or diode laser.

In addition to the benefits provided by the photoconducting properties of III-N, the method of fabricating the III-N LASS switch can employ epitaxial growth of the III-N photoconductor on sapphire and silicon carbide substrates, which also have highly desirable properties. For example, growing the photoconductor on the substrate reduces the cost of fabricating the LASS switch of the present invention in relation to conventional silicon LASS switches because it is not necessary to first fabricate the photoconductor and thereafter solder the photoconductor to the substrate waveguide. For microwave applications, sapphire has a high voltage breakdown and suffers from only low RF losses at high frequencies when compared to conventional substrates. For power switch applications, the thermal conductivity of silicon carbide accommodates high power dissipation. The III-N LASS switch of the present invention is also preferably constructed from films and substrates that are chemically and mechanically robust, and can be grown in single layer or multilayer structures to optimize their photonic properties.

In one embodiment, the LASS switch comprises a substrate, such as a sapphire substrate or a silicon carbide substrate, with two opposed major surfaces. The substrate includes a ground layer, such as a metallized back plane, on the second surface. Extending laterally across the first surface of the substrate, the LASS switch includes at least one pair of electrically conductive electrodes. Each electrode of the pair of electrodes is spaced apart from one another to thereby define a gap. Additionally, the LASS switch includes at least one III-nitride-based photoconductor, such as a gallium nitride (GaN) photoconductor, extending laterally across at least part of the surface of the substrate opposite the metallized back plane, and extending across the gap defined between the pairs of electrically conductive electrodes.

In one embodiment, each pair of electrodes includes first and second electrodes. In this embodiment, the laser activated switch further includes first and second terminals electrically connected to the first and second electrodes, respectively. For example, each pair of electrodes can include a positive and negative electrode connected to a positive and negative terminal, respectively. The first and second terminals of the LASS switch can be connected to positive and negative voltage supplies, respectively, so that the first electrode of each pair of electrodes has an opposite polarity from the second electrode.

In operation, the LASS switch utilizes the photoconductivity property of III-N whereby its resistance decreases as the III-N photoconductor is illuminated. In various embodiments, the laser activated switch can produce a pulse and/or switchably produce a current. The LASS switch operates by first charging each pair of electrodes so that the first electrodes are charged with an opposite polarity than the second electrodes. For example, the first electrodes may be charged with a positive polarity while the second electrodes are charged with a negative polarity.

In embodiments where the LASS switch produces a pulse, such as a microwave pulse, the photoconductors are first illuminated to thereby reduce its resistance. Reducing the resistance of the photoconductors in turn discharges each pair of electrodes to thereby produce a standing wave in the substrate, which, in turn, creates a train of pulses. Illuminating each photoconductor at different times, such as by specifying the angle at which the light strikes the photoconductors, can shape the pulse.

In one embodiment, the incident light can be generated at a location remote from the LASS switch and thereafter delivered to the photoconductors, such as via an optical fiber. In this embodiment, the incident light can be generated using any of a number of sources, such as a solid-state laser, a III-nitride-based laser and a light emitting diode.

In embodiments where the LASS switch operates to switchably produce a current, the switch includes first and second terminals. The terminals are connected to positive and negative voltage supplies, respectively. Each pair of electrodes are then charged with opposed polarities. Next, the switching element (i.e., III-N photoconductor), is illuminated to thereby reduce its resistance. The resulting discharge of each pair of electrodes produces the current flowing from the first terminal to the second terminal.

The present invention also provides a method for fabricating the laser activated switch. First, the ground layer is deposited on one surface of the substrate. Then, a composite switching layer including the pairs of electrodes and the photoconductors is formed upon the surface of the substrate opposite the ground layer. The composite switching layer is formed by forming each electrode of each pair of electrodes to be spaced apart from one another to thereby define a gap, and forming the photoconductors to extend across each gap. In embodiments in which the laser activated switch switchably produces the current, the first and second electrodes are then connected to the first and second terminals, respectively, to facilitate current flow therebetween upon illumination of the laser activated switch.

In one embodiment, the composite switching layer is formed by first forming the photoconductors by depositing a photoconductive material upon the substrate, and thereafter forming each pair of electrodes on the photoconductive material. For example, in embodiments in which the substrate is made from sapphire or silicon carbide, the photoconductors can be deposited by epitaxially growing the photoconductive material on the substrate, such as by molecular beam epitaxy (MBE) or metalorganic chemical vapor deposition (MOCVD). In another embodiment, each pair of electrodes is formed on the substrate, with the photoconductors thereafter deposited to extend across the gaps defined by the electrodes. In this embodiment, the gap defined by each pair of electrodes exposes at least a portion of the substrate on which a respective photoconductor can be deposited, such as by MBE or MOCVD. In embodiments where the substrate is made from sapphire or silicon carbide, the photoconductors can be deposited on the exposed portion of the substrate between each pair of electrodes so that at least a portion of the photoconductors contacts each electrode of each pair of electrodes.

The present invention therefore provides an improved LASS switch that utilizes the photoconductive properties of III-N to reduce the cost of the LASS switch in relation to conventional silicon LASS switches, while providing improved performance. In addition, the photoconducting properties of III-N also allow the LASS switch of the present invention to operate as a monolithic, high frequency LASS microwave source and/or a photonically controlled power switch. Advantageously, using a III-N based photoconductor makes the LASS of the present invention particularly suitable for high temperature applications since the relatively large band gap reduces thermally generated carriers. In addition to the photoconductive properties of III-N, utilizing a substrate made from materials such as sapphire or silicon carbide further supports high temperature operation due to their relatively high breakdown voltage while allowing the photoconductive material to be epitaxially grown on the substrate, as opposed to the costly procedure of fabricating the photoconductors and thereafter soldering them into the substrate waveguide.

### BRIEF DESCRIPTION OF THE DRAWINGS

Having thus described the invention in general terms, reference will now be made to the accompanying drawings, which are not necessarily drawn to scale, and wherein:

FIG. 1 is a perspective view of one embodiment of the present invention wherein the laser activated switch is used to produce a pulse;

FIG. 2 is a top view of one embodiment of the present invention wherein the laser activated switch is used to produce a pulse;

FIG. 3 is a perspective view of one embodiment of the present invention wherein the laser activated switch is used to switchably produce a current;

FIG. 4 is a top view of the laser activated switch used to switchably produce a current, according to one embodiment of the present invention;

FIG. 5 is a flow chart illustrating a method of producing a pulse according to one embodiment of the present invention;

FIG. 6 is a flow chart illustrating one embodiment of a method for switchably producing a current according to the present invention; and

FIGS. 7A and 7B are flow charts illustrating various embodiments of a method of fabricating a laser activated switch according to the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

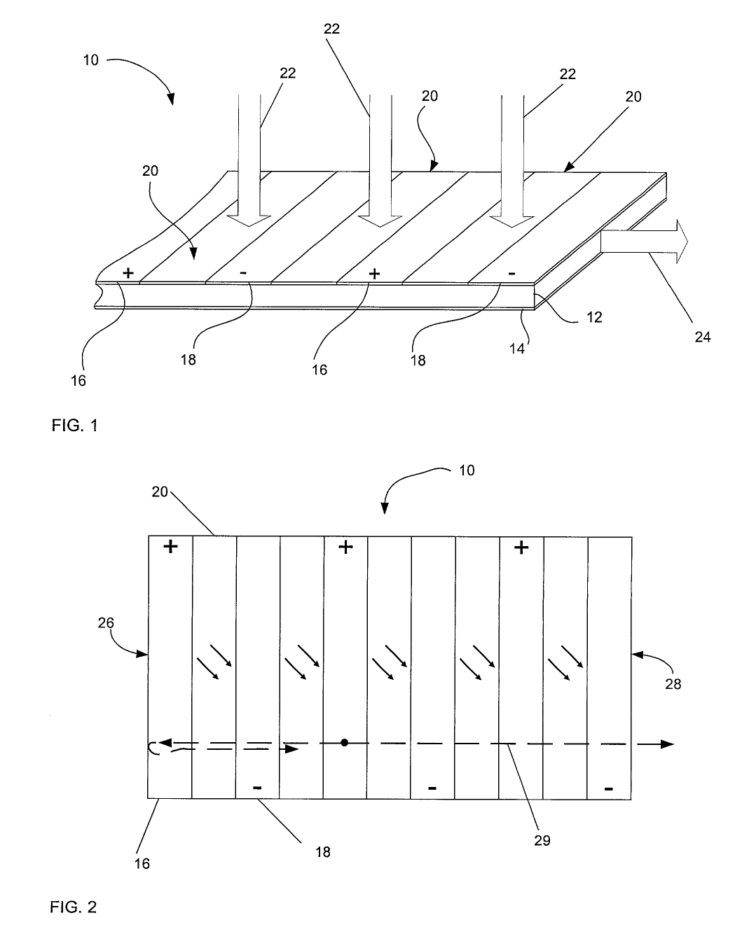

Referring to FIGS. 1 and 2, according to one embodiment of the present invention, the laser activated switch 10 is capable of generating a pulse 24, such as a radio frequency pulse. The laser activated switch of this embodiment includes a substrate 12, such as sapphire or silicon carbide, that acts as a rectangular waveguide for the produced pulse. The substrate extends longitudinally between opposed first 26 and second 28 ends and has first and second opposed surfaces. The second surface includes a ground layer 14 made from an electrically conductive material. The ground layer can be made of a variety of different electrically conductive materials, such as gold, silver, aluminum or any of a number of different metals.

The first surface of the substrate 12 includes a composite switching layer having at least one pair of electrically conductive electrodes, including a first electrode 16 and a second electrode 18, extending laterally across the substrate. The first and second electrodes are capable of having opposed polarities, such as positive and negative polarities, respectively. Whereas the substrate includes at least one pair of electrodes, in a preferred embodiment the substrate includes multiple pairs of electrodes, including as many as fifteen to twenty or more pairs of electrodes. In this regard, the more pairs of a given length of substrate, the more polarity the electrodes can handle, up to limits described below. The electrodes can be constructed from a variety of different electrically conductive materials, such as gold, silver, aluminum or any of a number of different metals. The electrodes in each pair, and the pairs of electrodes, are spaced apart from one another to have a gap in between adjacent electrodes. Additionally, to adhere the electrodes to the first surface of the substrate, an adhesive layer, such as a titanium layer, can be placed between the first surface of the substrate and the electrodes.

Also included on the first surface of the substrate 12, the composite switching layer includes at least one, but preferably multiple, switching elements 20 that extend laterally across at least a part of the substrate and across the gaps defined by the electrodes 16, 18. The switching elements are preferably made from a III-nitride (III-N) based material, such as an aluminum gallium indium nitride (AlGaInN) compound material. The photoconducting properties of the III-N based material cause the resistance of the material to decrease as the material is exposed to light 22, particularly light above a frequency corresponding to the band-gap energy, such as 6×10¹⁴ Hertz. The photoconducting properties of III-N based materials also produce many advantages over conventional silicon LASS switches. For example, III-N based materials reduce the cost of the laser activated switch of the present invention over conventional silicon LASS switches since the III-N photoconductive material can be epitaxially grown upon the substrate, while allowing the laser activated switch to operate as a monolithic, high frequency LASS microwave source and/or a photonically controlled power switch for high temperature applications. In this regard, the photoconductive material has a relatively large band gap, such as 3 eV to 6 eV for AlGaInN, in order to limit thermally generated carriers that otherwise lead to current leakage and breakdown.

The physical dimensions of the laser activated switch 10, including the substrate 12, ground layer 14, electrodes 16, 18 and switching elements 20 can vary depending on the application and desired output pulse from the laser activated switch. The length and width of the substrate, for example, can determine the frequency and pulse width of the pulse produced in the substrate, as such are known to those skilled in the art. Also, for example, the length of the electrodes can at least partially determine the voltage level to which each electrode can be charged. But it must be kept in mind that the upper limit of the voltage level to which each electrode can be charged can be determined by the voltage breakdown of the substrate and/or the switching elements.

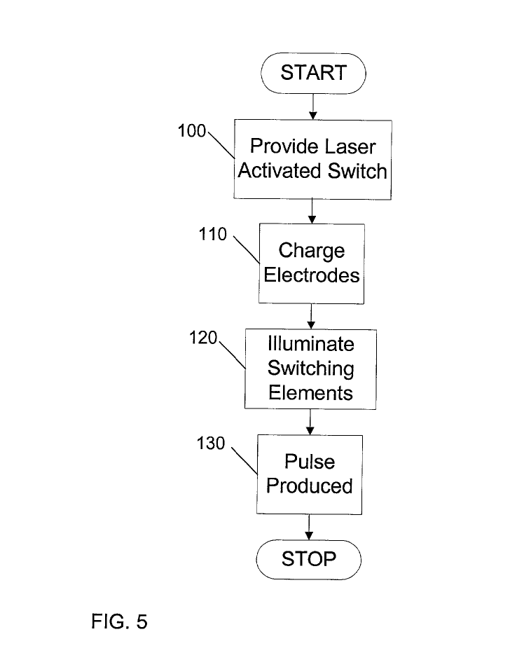

Referring to FIGS. 1, 2 and 5, in operation, the method of producing the pulse 24 begins by charging each pair of electrodes 16, 18 of the laser activated switch 10 with its respective polarity (blocks 100 and 110). For example, the first electrodes could be charged to a positive voltage, such as +5 to +10 kilovolts, while the negative electrodes are charged to a negative voltage such as −5 to −10 kilovolts. Whereas the electrodes can be charged to the same voltage, the electrodes can each be charged to different voltages without departing from the spirit and scope of the present invention. Also, whereas the electrodes can be charged to any of a number of different voltages, the voltage level should be no greater than the dielectric strength of the substrate. The electrodes can be charged according to any method known to those skilled in the art, such as, for example, electrically connecting the electrodes to a charging circuit and thereafter electrically disconnecting the charging circuit after the electrodes are charged.

After the electrodes 16, 18 are charged to opposed polarities, the pulse 24 may be produced by illuminating the switching elements with a ray of light 22 (blocks 120 and 130). By illuminating the switching elements, their resistance decreases and, in turn, their conductivity increases such that the switching elements switch from non-conductive to conductive. The light is preferably at a wavelength shorter than the band gap of the switching elements 20, so that the ray of light is strongly absorbed into the switching elements. For example, for a switching element formed of AlGaInN having a band gap of 2.5 eV, the light preferably has a wavelength of no more than 500 nanometers. Also, to produce a pulse without waveform degradation, the light preferably has a rise time shorter than the propagation time of the RF field from one electrode to the next electrode. In the particular embodiment described below, the rise of the light is preferably no more than approximately 50 picoseconds. The ray of light can be produced and delivered by any of a number of different methods, such as a III-N light emitting diode (LED) array or a III-N laser array applied directly to the switching elements as such as are known to those skilled in the art. Alternatively, the ray of light can be produced remote from the switching elements, such as by any of a number of sources, and delivered to the switching elements over a suitable transmission line, such as an optical fiber (not shown).

Increasing the conductivity of the switching elements 20 causes current to flow from the electrodes 16, 18 having the positive polarity to the electrodes having the negative polarity. The current produces a standing wave 29 in the substrate 12 which propagates in the substrate waveguide longitudinally toward the first 26 and second 28 ends. Typically, the laser activated switch is designed to emit a pulse via one end. As such, because of the infinite impedance at the opposite end of the substrate, the standing wave is reflected back to the end to which the pulse is emitted when the standing wave reaches the opposite end of the substrate. If the ray of light 22 is incident to the switching elements at the same time, the output pulse 24 has a Gaussian shape. But the shape of the pulse can be altered by applying the light to the switching elements at different times, such as by applying the ray of light to the laser activated switch at an angle such that the switching elements are triggered one after another along the length of the laser activated switch. By producing the standing wave at different times, the time that it takes for the standing wave to generate a pulse changes, thereby changing the shape of the pulse, such as to a multi-lobed pulse, for example. By changing the timing at which each of the switching elements is activated, the resulting temporal pulse profile can be controlled in a manner similar to that employed for the digital generation of pulse forms. The output pulse can be seen as the temporal superposition of the pulses produced by each of the individual switching elements.

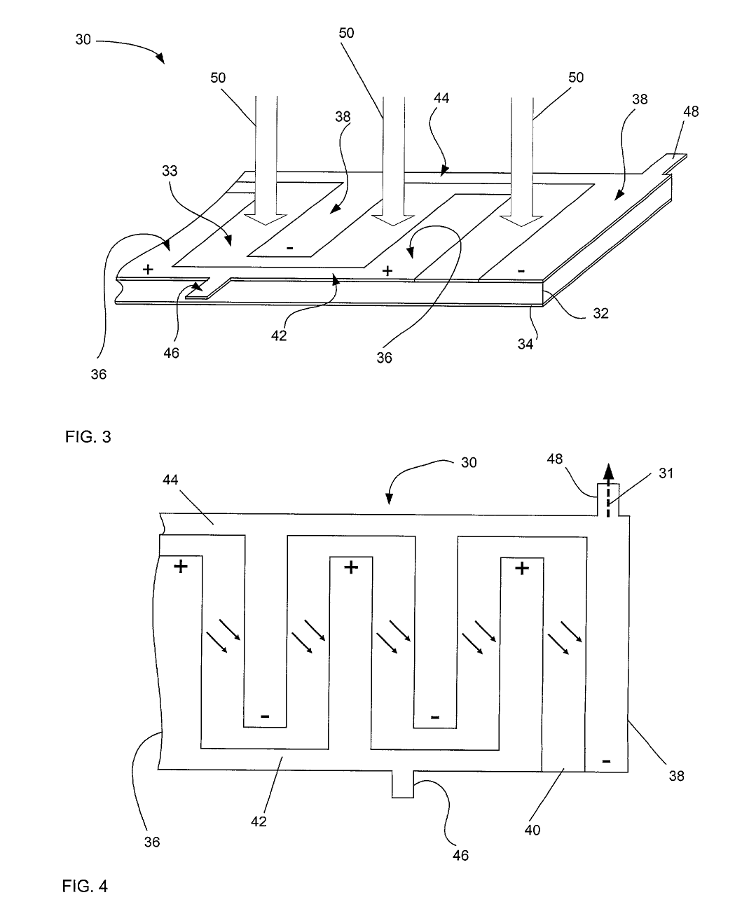

Referring to FIGS. 3 and 4, in another embodiment, the laser activated switch 30 is capable of acting as a photonically controlled power switch to switchably produce a current 31. In this embodiment, the laser activated switch further includes a first terminal 42 and a second terminal 44 electrically connected to the first and second electrodes, respectively, of each pair of electrodes 36, 38. The first and second terminals are capable of being connected to positive and negative voltage supplies (not shown), respectively, such as at first 46 and second 48 connection points, respectively. In this manner, the first and second electrodes can be charged to opposed polarities, such as positive and negative polarities, respectively. As previously stated, up to the breakdown voltage of the substrate 32 and/or switching elements 33, as the length of the electrodes increases, the voltage level to which the respective electrodes can safely be charged increases. It should be understood that the first and second terminals and first and second connection points of the illustrated embodiment are disposed on edges of the substrate for illustrative purposes only. The terminals and/or connection points can be disposed on other portions of the laser activated switch, or disposed at a location at or near, but not on, the substrate.

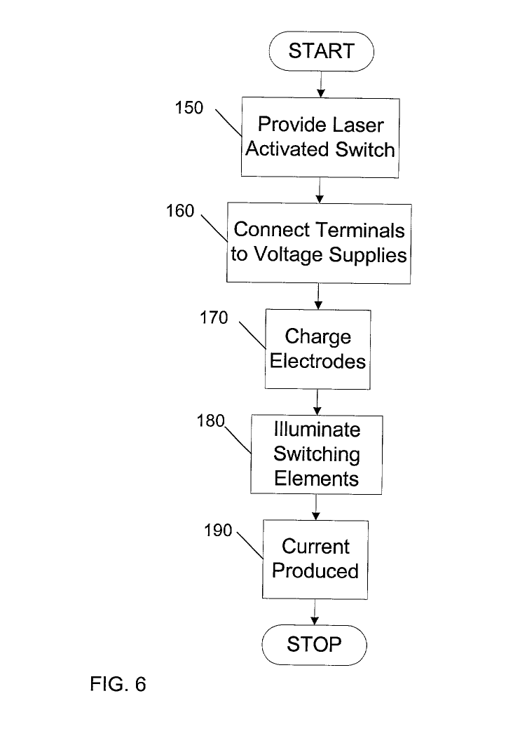

Referring to FIGS. 3, 4 and 6, in one embodiment, the laser activated switch 30 is capable of acting as a photonically controlled power switch that switchably produces a current 31. In this embodiment, in operation, the terminals 42, 44 are connected to their respective voltage supplies (blocks 150 and 160). The electrodes 36, 38 are then charged to their respective voltage levels having polarities (block 170). And again, the switching elements 40, i.e., photoconductors, are illuminated to increase their conductivity (block 180) and switch the switching elements from non-conductive to conductive. Also as before, current flows across the photoconductors from the electrodes having a positive polarity to the electrodes having a negative polarity. But in this embodiment, by interconnecting the electrodes of each pair to their respective terminals, and electrically connecting the terminals to voltage supplies, a current is produced that flows from the first, or positive, terminal to the second, or negative, terminal (block 190).

The substrate 32, made from materials such as silicon carbide, exhibits high thermal capabilities, i.e., a high breakdown voltage, and, thus, make the laser activated switch 30 ideal for high temperature photonically controlled switching applications. It is preferred to achieve the lowest voltage drop as possible across the switch to minimize power dissipation in the switch in the on state. For example, with sufficient illumination to drive the photoconductors to a resistance of one Ohm, a laser activated switch with dimensions of 50 millimeters by 100 millimeters, using 0.5 millimeter gaps between electrodes, could achieve an “on” state resistance of 10⁻⁴ Ohms. In this example, the laser activated switch would have approximately 100 Watts of average dissipation at a root-mean-square current of 1500 Amps. Because of the high dielectric strength of III-nitride films, such a switch could hold off 50 to 100 Kilovolts in the “off” state and, therefore, could switch 75 Megawatts of power.

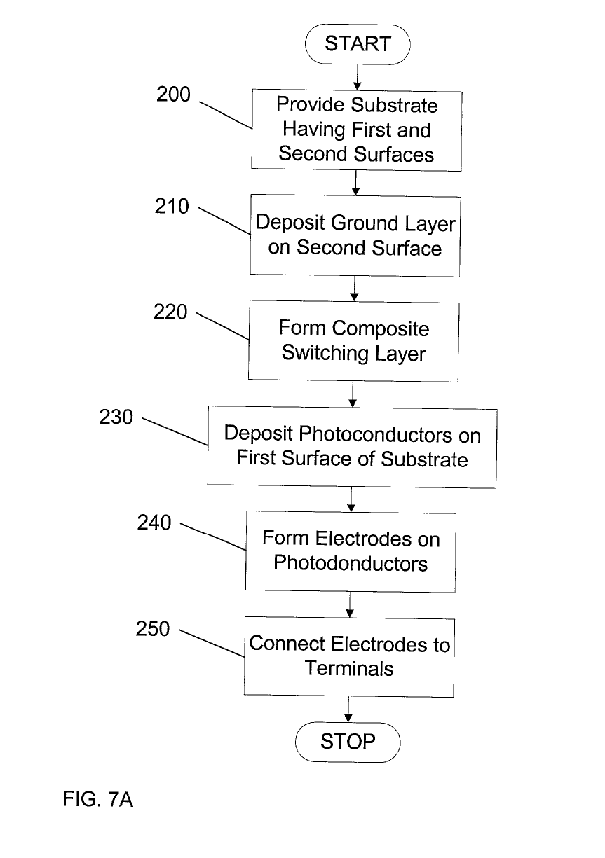

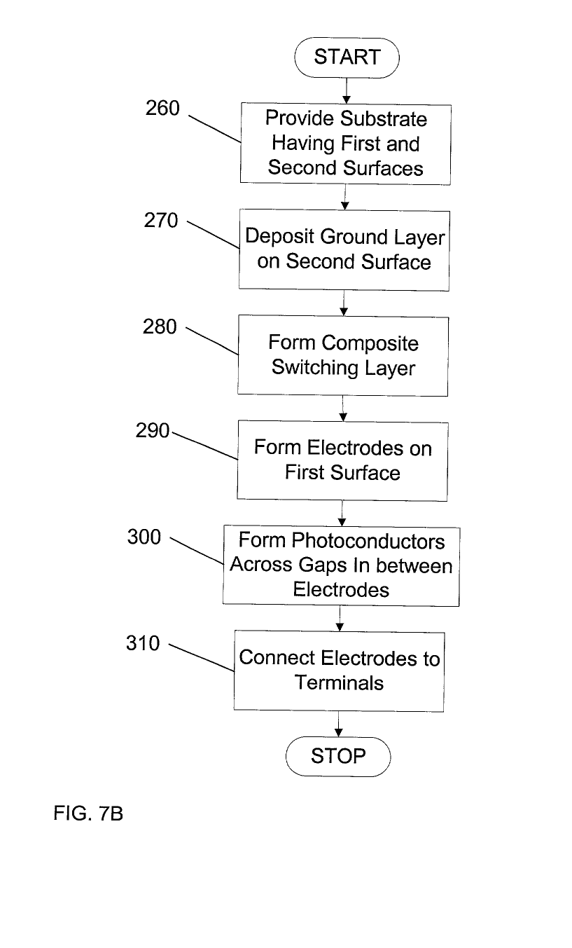

Referring to FIGS. 7A and 7B, the present invention also includes a method of producing a laser activated switch. After providing the substrate (block 200, 260), the ground layer is deposited on the second surface of the substrate (block 210, 270). The ground layer can be deposited by any of a number of different methods, but in one embodiment the second surface of the substrate is metallized to form the ground layer. After the ground layer is deposited, a composite switching layer comprising the pairs of electrodes and the switching elements, i.e., photoconductors, are formed on the first surface of the substrate (block 220, 280). In embodiments wherein the laser activated switch acts as a photonically controlled power switch, the electrodes are then connected to their respective terminals (block 310).

In one embodiment, one or more photoconductors are deposited on the first surface of the substrate, such as by any method known to those skilled in the art (block 230). But in a preferred embodiment, the photoconductors are deposited on the first surface by an epitaxial growth method, such, for example, as by MBE or MOCVD. Depositing the photoconductors on the substrate by an epitaxial growth method decreases the cost of the laser activated switch when compared to conventional silicon LASS switches because the photoconductors need not be separately fabricated and thereafter soldered onto the substrate waveguide. After the photoconductors are deposited, the pairs of electrodes are formed on or around the photoconductors (block 240), such as by plating metal onto portions of the photoconductors defined by a mask or the like. In another embodiment, the pairs of electrodes are formed on the first surface of the substrate (block 290). Then, the photoconductors are formed across the gaps defined by each pair of electrodes (block 300). In this embodiment, the locations of the electrodes and photoconductors are defined by a mask or the like.

The photoconductors and pairs of electrodes can be formed such that the photoconductors are situated in between each electrode across the gaps formed between the electrodes, or reside underneath the electrodes and extend across the gaps formed by the electrodes. No matter how the photoconductors are situated in relation to the electrodes, the photoconductors are preferably situated such that at least a portion of the electrodes contact each electrode that defines the gap across which the respective photoconductor extends. In this regard, the photoconductor can act as a conduit across which the current flows when the photoconductors are illuminated and become conductive.

The present invention therefore provides a laser activated switch that utilizes the photoconductive properties of III-N to operate as a monolithic, high frequency LASS microwave source and/or a photonically controlled power switch. Advantageously, using a III-N based photoconductor, the laser activated switch of the present invention particularly suitable for high temperature applications, in contrast to conventional silicon LASS switches. In addition to the photoconductive properties of III-N, utilizing a substrate made from materials such as sapphire or silicon carbide, the photoconductors can be epitaxially grown on the substrate, as opposed to the complex and costly procedures of fabricating the photoconductors and thereafter soldering them onto the substrate waveguide.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A laser activated switch comprising:
a substrate having major first and second opposed major surfaces including a ground layer on the second surface, wherein said substrate extends longitudinally between opposed first and second ends;
at least one pair of electrically conductive electrodes laterally extending across the first surface of said substrate, wherein each electrode of said pair of electrodes are spaced apart from one another to thereby define a gap; and
at least one switching element extending laterally across at least part of the first surface of said substrate, wherein said at least one switching element extends across the gap defined between said at least one pair of electrically conductive electrodes, and wherein said at least one switching element is constructed from a III-nitride-based material.

2. A laser activated switch according to claim 1, wherein each pair of electrodes is capable of having opposed polarities.

3. A laser activated switch according to claim 1, wherein said at least one switching element is constructed from a gallium nitride-based material.

4. A laser activated switch according to claim 1, wherein said substrate is selected from a group consisting of sapphire and silicon carbide.

5. A laser activated switch according to claim 1, wherein said at least one switching element has a controllably alterable resistance, wherein the resistance decreases when said at least one switching element is illuminated by light.

6. A laser activated switch according to claim 1, wherein each pair of electrodes includes first and second electrodes, and wherein the laser activated switch further comprises first and second terminals electrically connected to the first and second electrodes, respectively, of each pair of electrodes.

7. A laser activated switch according to claim 6, wherein said at least one switching element has a controllably alterable resistance, wherein the resistance decreases when said at least one switching element is illuminated by light.

8. A laser activated switch according to claim 7, wherein the first and second terminals are capable of being connected to positive and negative voltage supplies, respectively, such that the first electrode of each pair of electrodes has the opposite polarity from the second electrode, wherein when said at least one switching element is illuminated by light the resistance of said at least one switching element decreases such that each pair of electrodes discharges across the at least one switching element to thereby produce a current from the first terminal to the second terminal.

9. A laser activated switch according to claim 6, wherein said at least one switching element is constructed from a gallium nitride-based material.

10. A laser activated switch according to claim 6, wherein said substrate is selected from a group consisting of sapphire and silicon carbide.

11. A method of fabricating a laser activated switch comprising:
providing a substrate having major first and second opposed major surfaces, wherein said substrate extends longitudinally between opposed first and second ends;
depositing a ground layer upon the second surface of the substrate; and
forming a composite switching layer upon the first surface of the substrate, wherein the switching layer comprises at least one pair of electrically conductive electrodes and at least one III-nitride-based photoconductor, wherein forming the switching layer comprises forming each electrode of each pair of electrodes to be spaced apart from one another to thereby define a gap, and wherein forming the switching layer further comprises forming the at least one photoconductor to extend across the gap.

12. A method according to claim 11, wherein forming the at least one photoconductor comprises depositing the at least one photoconductor upon the first surface of the substrate, and wherein forming each pair of electrodes comprises forming the at least one pair of electrically conductive electrodes on the at least one photoconductor.

13. A method according to claim 12, wherein providing the substrate comprises providing a substrate made from a material selected from a group consisting of sapphire and silicon carbide, and wherein depositing the at least one photoconductor comprises epitaxially growing the at least one photoconductor on the substrate.

14. A method according to claim 12, wherein depositing the at least one photoconductor comprises depositing the at least one photoconductor by a deposition method selected from a group comprising molecular beam epitaxy and metalorganic chemical vapor deposition.

15. A method according to claim 11, wherein forming each pair of electrodes comprises forming the at least one pair of electrically conductive electrodes on the first surface of the substrate, and wherein forming the at least one photoconductor comprises depositing the at least one photoconductor to extend across the gap defined by each pair of electrodes.

16. A method according to claim 15, wherein providing the substrate comprises providing a substrate made from a material selected from a group consisting of sapphire and silicon carbide, wherein forming the at least one pair of electrodes comprises forming the at least one pair of electrodes such that the gap defined by each electrode of each pair of electrodes exposes at least a portion of the substrate, and wherein depositing the at least one photoconductor comprises depositing the at least one photoconductor on the substrate exposed by the gap, wherein the at least one photoconductor is deposited such that at least a portion of the at least one photoconductor contacts each electrode of each pair of electrodes.

17. A method according to claim 16, wherein depositing the at least one photoconductor comprises epitaxially growing the at least one photoconductor.

18. A method according to claim 17, wherein depositing the at least one photoconductor comprises depositing the at least one photoconductor by a deposition method selected from a group comprising molecular beam epitaxy and metalorganic chemical vapor deposition.

19. A method according to claim 11, wherein each pair of electrodes includes first and second electrodes, said method further comprising connecting the first and second electrodes to first and second terminals, respectively.

20. A method of producing a pulse comprising:
providing a laser activated switch comprising:
a substrate having major first and second opposed major surfaces;
at least one pair of electrically conductive electrodes on the first surface of the substrate, wherein each electrode of the pair of electrodes are spaced apart from one another to thereby define a gap; and
at least one photoconductor comprised of a III-nitride-based material extending across the gap defined between the at least one pair of electrodes;
charging each pair of electrodes with opposed polarities; and
illuminating the at least one photoconductor with light thereby reducing a resistance of the at least one photoconductor, wherein reducing the resistance of the at least one photoconductor discharges each pair of electrodes to thereby produce the pulse.

21. A method according to claim 20, wherein illuminating the at least one photoconductor comprises illuminating the at least one photoconductor with an incident ray of light.

22. A method according to claim 20, wherein illuminating the at least one photoconductor comprises illuminating the at least one photoconductor with a ray of light at a predefined angle to the first surface of the substrate to thereby shape the pulse.

23. A method according to claim 20 further comprising generating a ray of light at a location remote from the laser activated switch and thereafter delivering the ray of light to the at least one photoconductor to illuminate the at least one photoconductor.

24. A method according to claim 23, wherein delivering the ray of light comprises delivering the ray of light via an optical fiber.

25. A method according to claim 23, wherein generating the ray of light comprises generating the ray of light with a source selected from a group consisting of a solid-state laser, a III-nitride-based laser and a light emitting diode.

26. A method of switchably producing a current comprising:
providing a laser activated switch comprising:
a substrate having major first and second opposed major surfaces;
at least one pair of first and second electrically conductive electrodes on the first surface of the substrate, wherein each electrode of the pair of electrodes are spaced apart from one another to thereby define a gap, and wherein the first and second electrodes are connected to first and second terminals, respectively; and
at least one photoconductor comprised of a III-nitride-based material extending across the gap defined between the at least one pair of electrodes;
connecting the first and second terminals to positive and negative voltage supplies, respectively;
charging each pair of electrodes with opposed polarities; and
illuminating the at least one switching element with light thereby reducing a resistance of the at least one photoconductor, wherein reducing the resistance of the at least one photoconductor discharges each pair of electrodes to thereby produce the current from the first terminal to the second terminal.

27. A method according to claim 26 further comprising generating a ray of light at a location remote from the laser activated switch and thereafter delivering the ray of light to the at least one photoconductor to illuminate the at least one photoconductor.

28. A method according to claim 27, wherein delivering the ray of light comprises delivering the ray of light via an optical fiber.

29. A method according to claim 27, wherein generating the ray of light comprises generating the ray of light with a source selected from a group consisting of a solid-state laser, a III-nitride-based laser and a light emitting diode.
